(19) United States
(12) Patent Application Publication
(10) Pub. No.: US 2024/0389412 A1
(43) Pub. Date: Nov. 21, 2024

(54) DISPLAY DEVICE

(71) Applicant: Sharp Display Technology Corporation, Kameyama City, Mie (JP)

(72) Inventors: Hiroyuki MADONO, Kameyama City, Mie (JP); Yoshifumi OHTA, Kameyama City, Mie (JP); Takeshi HIRASE, Kameyama City, Mie (JP); Takashi TOYODA, Kameyama City, Mie (JP)

(21) Appl. No.: 18/691,546

(22) PCT Filed: Dec. 7, 2021
(86) PCT No.: PCT/JP2021/044808

§ 371 Date: Mar. 13, 2024

(51) Int. Cl. H10K 59/131

(52) U.S. Cl. CPC H10K 59/131

(57) ABSTRACT

A display device includes a dummy contact hole formed away from a portion of a routed wiring portion in a width direction, and formed to overlap with another portion of the routed wiring portion in the width direction. The routed wiring portion bypasses a first region and passes through a second region.

### TECHNICAL FIELD

The present invention relates to a display device.

### BACKGROUND ART

A known display device includes a signal wiring formed to bypass a camera hole (see Patent Documents 1 and 2).

### CITATION LIST

### Patent Literature

[Patent Document 1] International Publication No. WO/2019/198163
[Patent Document 2] Japanese Unexamined Patent Application Publication No. 2009-047902

### SUMMARY OF INVENTION

### Technical Problems

A display device including a camera hole has a problem of developing unevenness in displaying an image around the camera hole. In order to reduce the display unevenness around the camera hole, dummy contact holes could be concentrically and equally arranged around the camera hole. This is because the number and density of the contact holes change the characteristics of thin-film transistors (TFTs) for display elements provided in a display area of the display device.

However, a spacing between adjacent routed signal wirings bypassing the camera hole is narrower than a spacing between adjacent signal wirings passing through the display area. Hence, when the dummy contact holes are formed over the routed wirings in order to be concentrically and equally arranged around the camera hole, the routed wirings might be broken at level differences of the dummy contact holes.

One aspect of the present invention sets out to provide a display device capable of reducing display unevenness around a camera hole while avoiding breaks of a routed wiring.

### Solution to Problems

In order to solve the above problems, a display device according to an aspect of the present invention includes a plurality of scanning signal wirings; a plurality of data signal wirings intersecting with the plurality of scanning signal wirings; and a plurality of subpixel circuits each disposed to a corresponding one of a plurality of intersections of the plurality of scanning signal wirings and the plurality of data signal wirings. The display device includes a first region and a second region not provided with the plurality of subpixel circuits. The first region is surrounded with the second region, and the second region is surrounded with the display area. When viewed in a direction perpendicular to the display area, each of a plurality of signal wirings includes a routed wiring portion that bypasses the first region and passes through the second region. The plurality of signal wirings at least include: scanning signal wirings included in the plurality of scanning signals; or data signal wirings included in the plurality of data signal wirings. The display device includes a dummy contact hole formed away from a portion of the routed wiring portion in a width direction, and formed to overlap with another portion of the routed wiring portion in the width direction.

### Advantageous Effects of Invention

One aspect of the present invention can reduce display unevenness around a camera hole while avoiding breaks of a routed wiring.

### BRIEF DESCRIPTION OF DRAWINGS

FIG. 1 is a flowchart showing an exemplary method for producing a display device.

FIG. 2 is a cross-sectional view of an exemplary configuration of a display area of the display device.

FIG. 3(a) is a plan view of a configuration of the display device, and FIG. 3(b) is a circuit diagram illustrating a circuit configuration of a subpixel included in the display area.

FIG. 4 is a plan view of a configuration around an imaging hole according to a first embodiment.

FIG. 5 is an enlarged plan view of a portion B1 illustrated in FIG. 4.

FIG. 6 is an enlarged plan view of a portion B2 illustrated in FIG. 5.

FIG. 7 is a plan view showing dummy contact holes according to a comparative example.

FIG. 8 is an enlarged plan view of a portion B3 illustrated in FIG. 7.

FIG. 9 is cross-sectional view taken along line C-C illustrated in FIG. 8.

FIG. 10 is another enlarged plan view of the portion B1 illustrated in FIG. 4.

FIG. 11 is an enlarged plan view of a portion B4 illustrated in FIG. 10.

FIG. 12 is a plan view showing dummy contact holes provided to the display device.

FIG. 13 is a cross-sectional view of a dummy contact hole formed between a display area and a routed wiring of the display device.

FIG. 14 is a cross-sectional view of a dummy contact hole formed under a top gate metal of the display device.

FIG. 15 is a cross-sectional view of a dummy contact hole formed under a routed wiring of the display device.

FIG. 16 is a cross-sectional view showing the dummy contact holes provided to the display device.

### DESCRIPTION OF EMBODIMENTS

In the description below, the term “same layer” means that constituent features are formed in the same process (in the same film forming process). The term “below” means that a constituent feature is formed in a previous process before a comparative layer is formed. The term “above” means that a constituent feature is formed in a successive process after a comparative layer is formed.

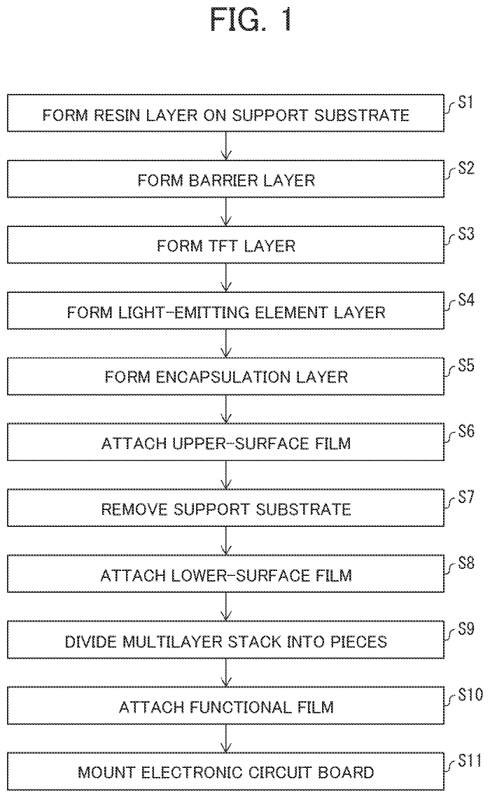

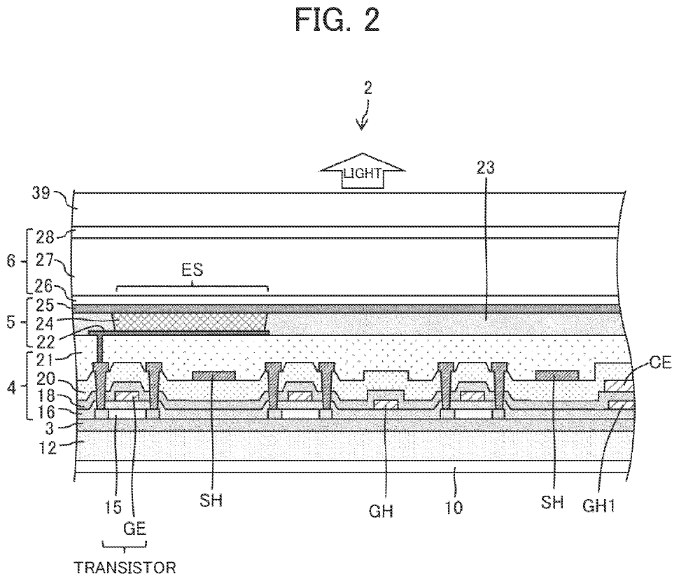

FIG. 1 is a flowchart showing an exemplary method for producing a display device. FIG. 2 is a cross-sectional view of an exemplary configuration of a display unit of the display device.

When a flexible display device is produced, first, as shown in FIGS. 1 and 2, a resin layer 12 is formed on a light-transparent support substrate (e.g., a mother glass) (Step S1). Next, a barrier layer 3 is formed (Step S2). Next, a TFT layer 4 is formed (Step S3). Next, a light-emitting element layer 5 of a top-emission type is formed (Step S4). Next, a encapsulation layer 6 is formed (Step S5). Next, an upper-surface film is attached to the encapsulation layer 6 (Step S6).

Next, the support substrate is removed from the resin layer 12 with, for example, a laser beam emitted on the support substrate (Step S7). Next, a lower-surface film 10 is attached to a lower surface of the resin layer 12 (Step S8). Next, a multilayer stack including the lower-surface film 10, the resin layer 12, the barrier layer 3, the TFT layer 4, the light-emitting element layer 5, and the encapsulation layer 6 is divided into a plurality of pieces (Step S9). Next, a functional film 39 is attached to an obtained piece (Step S10). Next, an electronic circuit board (e.g., an IC chip and an FPC) is mounted on a portion (a terminal unit) outside (in a non-display area; namely, a picture frame) the display area in which a plurality of subpixels are formed (Step S11). Note that Steps S1 to S11 are carried out on a display device producing apparatus (including a deposition apparatus that carries out each of Steps S1 to S5).

Examples of a material of the resin layer 12 include polyimide. Note that the resin layer 12 can be replaced with a two-layer resin film (e.g., a polyimide film) and an inorganic insulating film sandwiched between the two layers.

The barrier layer 3 is a layer that prevents foreign substances such as water and oxygen from entering the TFT layer 4 and the light-emitting element layer 5. The barrier layer 3 may be a silicon oxide film, a silicon nitride film, or a silicon oxynitride film formed by the CVD. Alternatively, the barrier layer 3 may be a multilayer film including these films.

The TFT layer 4 includes: a semiconductor film 15; an inorganic insulating film 16 (i.e., a gate insulating film) above the semiconductor film 15; a gate electrode GE and a gate wiring GH above the inorganic insulating film 16; an inorganic insulating film 18 above the gate electrode GE and the gate wiring GH; a capacitive electrode CE above the inorganic insulating film 18; an inorganic insulating film 20 above the capacitive electrode CE; a source wiring SH above the inorganic insulating film 20; and a planarization film 21 above the source wiring SH.

The semiconductor film 15 is formed of, for example, low-temperature polysilicon (LTPS) or an oxide semiconductor (e.g., an In—Ga—Zn—O-based semiconductor). A transistor (a TFT) is formed to include the semiconductor film 15 and the gate electrode GE. In FIG. 2, the transistor is a top-gate transistor. Alternatively, the transistor may be a bottom-gate transistor.

Each of the gate electrode GE, the gate wiring GH, the capacitive electrode CE, and the source wiring SH is either a metal monolayer film, or a metal multilayer film, containing at least one of, for example, aluminum, tungsten, molybdenum, tantalum, chromium, titanium, or copper. The TFT layer 4 may include one semiconductor layer and three metal layers (a first metal layer, a second metal layer, and a third metal layer).

Each of the inorganic insulating films 16, 18, and 20 is formed by, for example, the CVD, and made of a silicon oxide (SiOₓ) film, a silicon nitride (SiNₓ) film, or a multilayer film including these films. The planarization film 21 may be formed of, for example, an applicable organic material such as polyimide or acrylic.

The light-emitting element layer 5 includes: an anode 22 above the planarization film 21, an edge cover 23 providing insulation and covering an edge of the anode 22; an electroluminescence (EL) layer 24 above the edge cover 23; and a cathode 25 above the EL layer 24. In forming the edge cover 23, for example, an organic material such as polyimide or acrylic is applied. After that, the applied organic material is patterned by photolithography to form the edge cover 23.

For each of the subpixels, a light-emitting element ES (e.g., an organic light-emitting diode: OLED, and a quantum-dot light-emitting diode: QLED), which includes the anode 22 and the EL layer 24 both shaped into an island, and the cathode 25, is formed in the light-emitting element layer 5. A control circuit for the light-emitting element ES is formed in the TFT layer 4. The light-emitting element and the control circuit for the light-emitting element constitute a subpixel circuit.

The EL layer 24 is a multilayer including: a hole injection layer; a hole transport layer; a light-emitting layer; an electron transport layer; and an electron injection layer, all of which are stacked on top of another in the stated order from below. The light-emitting layer is shaped into an island shape in an opening (for each subpixel). The light-emitting layer is formed by vapor deposition or inkjet printing. The other layers are shaped into island shapes or into monolithic shapes (the common-layer edge cover 23). Moreover, one or more of the hole injection layer, the hole transport layer, the electron transport layer, and the electron injection layer can be omitted.

When the light-emitting layer is formed for an OLED by vapor deposition, a fine metal mask (an FMM) is used. The FMM is a sheet (e.g., invar) including many openings. An organic material passing through one opening forms a light-emitting layer (corresponding to one subpixel) shaped into an island shape.

The light-emitting layer for a QLED may be formed of, for example, a solvent into which quantum dots are dispersed. The solvent is applied by inkjet printing to form the light-emitting layer shaped into an island shape (corresponding to one subpixel).

The anode 22 is formed of a multilayer including, for example, indium tin oxide (ITO) and either silver (Ag) or an alloy containing Ag. The anode 22 is reflective to light (i.e., a reflective electrode). The cathode 25 can be formed of a light-transparent conductive material such as a MgAg alloy (an ultrathin film), ITO, or indium zinc oxide (IZO) (i.e., a transparent electrode).

If the light-emitting element ES is an OLED, holes and electrons recombine together in the light-emitting layer by a drive current between the anode 22 and the cathode 25, which forms an exciton. While the exciton transforms to the ground state, light is released. Because the cathode 25 is transparent to light and the anode 22 is reflective to light, the light emitted from the EL layer 24 travels upwards. This is how the light-emitting element layer 5 is of a top emission type.

If the light-emitting element ES is a QLED, holes and electrons recombine together in the light-emitting layer by a current between the anode 22 and the cathode 25, which forms an exciton. While the exciton transforms from the conduction band level to the valence band level of the quantum dots, light (fluorescent light) is released.

The light-emitting element layer 5 may include a light-emitting element (such as an inorganic light-emitting diode) other than the OLED and the QLED.

The encapsulation layer 6 is transparent to light, and includes: an inorganic encapsulation film 26 covering the cathode 25; an organic buffer film 27 above the inorganic encapsulation film 26; and an inorganic encapsulation film 28 above the organic buffer film 27. The encapsulation layer 6 covering the light-emitting element layer 5 prevents foreign substances such as water and oxygen from penetrating into the light-emitting element layer 5.

Each of the inorganic encapsulation film 26 and the inorganic encapsulation film 28 is an inorganic insulating film. For example, the inorganic insulating film can be a silicon oxide film, a silicon nitride film, or a silicon oxynitride film formed by the CVD. Alternatively, the inorganic insulating film can be a multilayer film including these films. The organic buffer film 27 is a light-transparent organic film exhibiting a planarizing effect. The organic buffer film 27 can be made of an applicable organic material such as acrylic. The organic buffer film 27 can be formed by, for example, inkjet printing. In order to block the droplets in the inkjet printing, a bank may be provided to the non-display area.

The lower-surface film 10 is attached to the lower surface of the resin layer 12 after the support substrate is removed. Hence, the lower-surface film 10 provides the display device with excellent flexibility. The lower-surface film 10 is, for example, a PET film. The functional film 39 has at least one of, for example, an adaptive optics correction function, a touch sensor function, and a protection function.

Described above is a case where the display device is a flexible display device. In the case where a non-flexible display device is produced, such typical works as formation of the resin layer and replacement of a base material are unnecessary. Hence, for example, the glass substrate is subjected to stacking steps of Steps S2 to S5. After that, the process proceeds to Step S9.

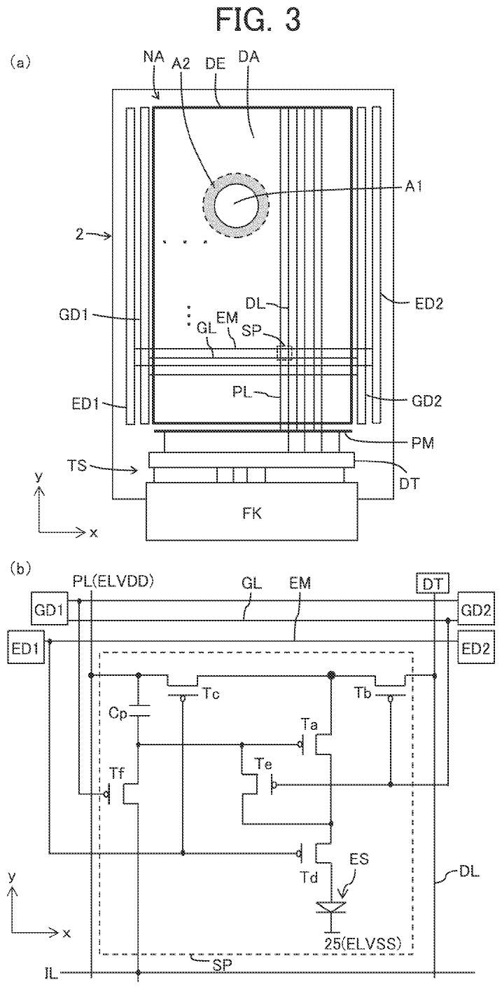

FIG. 3(a) is a plan view of a configuration of the display device, and FIG. 3(b) is a circuit diagram illustrating a circuit configuration of a subpixel included in the display area. As illustrated in FIG. 3, the display device 2 includes: a display area DA including a plurality of subpixels SP; and a picture-frame region (a non-display area) NA surrounding the display area DA. The display area DA is provided with: a plurality of scanning signal wirings GL extending in an x-direction; a plurality of data signal wirings DL extending in a y-direction perpendicular to the x-direction; a plurality of light-emission control lines EM extending in the x-direction; and a plurality of high-voltage power supply lines PL extending in the y-direction. The high-voltage power supply lines PL are supplied with ELVDD through a trunk wiring PM.

A subpixel circuit SP including the light-emitting element ES is connected to a data signal wiring DL, a scanning signal wiring GL, a light-emission control line EM, a high-voltage power supply line PL, and an initialization power supply line IL. Note that a capacitor Cp has: one electrode connected to the high-voltage power supply line PL; and another electrode connected to a gate terminal of a drive transistor Ta. The drive transistor Ta has: a source terminal connected to the data signal wiring DL through a write transistor Tb; and a drain terminal connected to the light-emitting element ES through a transistor Td. The data signal wiring DL is connected to a driver chip DT. The scanning signal wiring GL is connected to gate drivers GD1 and GD2. The light-emission control line EM is connected to emission drivers ED1 and ED2. The gate drivers GD1 and GD2 and the emission drivers ED1 and ED2 are monolithically formed in the TFT layer 4 included in the picture-frame region NA.

The gate drivers GD1 and GD2 are arranged on opposing sides of the display area DA in a shorter-side direction, so that the display area DA is sandwiched between the gate drivers GD1 and GD2. The emission drivers ED1 and ED2 are also arranged on the opposing sides of the display area DA in the shorter-side direction, so that the display area DA is sandwiched between the emission drivers ED1 and ED2. Note that the emission drivers ED1 and ED2 are positioned outside the gate drivers GD1 and GD2 (i.e., positioned toward edges of the device).

The driver chip DT (a source driver) is mounted on a terminal unit TS in the picture-frame region NA. The data signal wirings DL and the trunk wiring PM are connected to the driver chip DT. The data signal wirings DL may be connected to the driver chip DT through an SSD circuit (i.e., a time-division drive switch circuit monolithically formed in the TFT layer 4). A flexible circuit board FK (i.e., a substrate on which such components as a processor and a power supply circuit are mounted) is connected to the terminal unit TS.

In this embodiment, a region A1 (i.e., a first region; namely, a camera hole) and a region A2 (i.e., a second region) are provided behind an edge DE (an outer edge) of the display area DA. The first region A1 is not provided with the subpixel circuit and transparent to light. The second region surrounds the region A1, and is not provided with the subpixel circuits. The region A2, surrounded with the display area DA, is a routing region for routing signal lines. The region A1 and the region A2 are non-display areas provided in the display area DA. The display area DA is a region other than the regions A1 and A2 in the display area DA.

The region A1 is, for example, a light-transparent region for imaging. A plurality of data signal wirings and a plurality of scanning signal wirings are laid across the region A2; that is, the routing region.

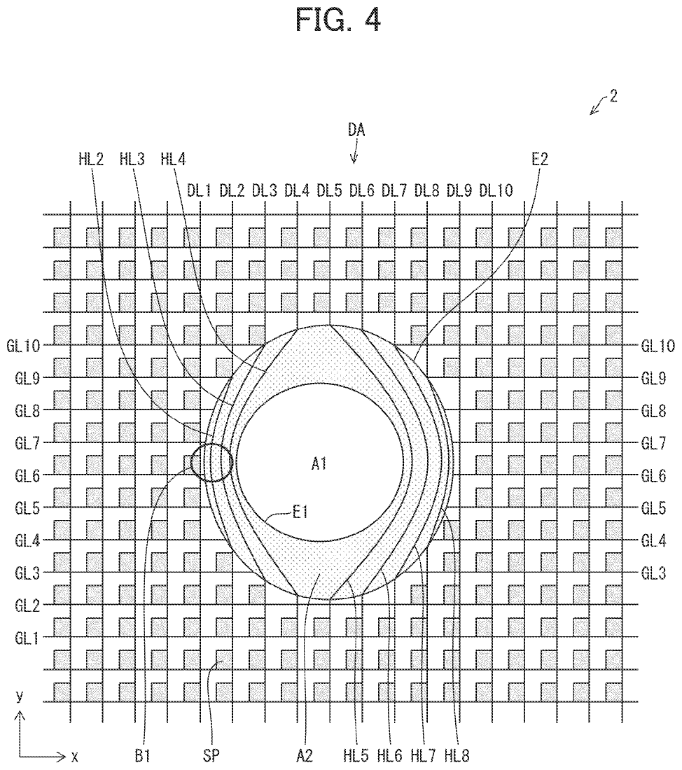

FIG. 4 is a plan view of a configuration around the first region A1 (i.e., the first region; namely, the camera hole) according to this embodiment. As illustrated in FIG. 4, the display area DA includes: data signal wirings DL1 to DL10; scanning signal wirings GL1 and GL2; and pairs of scanning signal wirings GL3 to GL10. Hence, when viewed in a direction perpendicular to the display area DA, the data signal wirings DL2 to DL8 are formed to be laid across the region A2.

For example, the subpixel circuits SP are formed in the vicinity of the intersections of the scanning signal wirings GL1 and the data signal wirings DL1 in the display area DA; however, the subpixel circuits SP are not formed either in the region A1 or in the region A2. A subpixel circuit SP includes: a light-emitting element; and a control circuit for the light-emitting element (see FIG. 3). In plan view, the region A1 is larger than at least a region occupied with the subpixel circuit SP.

Each of the data signal wirings DL2 to DL8 includes a corresponding one of routed wiring portions HL2 to HL8 that bypass the region A1 and pass through the region A2.

In FIG. 4, the routed wiring portions HL2 to HL8 laid across the region A2 pass out of an edge μl of the region A1. That is, the routed wiring portions HL2 to HL8 laid across the region A2 are routed to avoid the region A1 (to bypass the region A1), and neither the data signal wirings nor the scanning signal wirings are arranged in the region A1.

The pairs of scanning signal wirings GL3 to GL10 are connected to the gate drivers GD1 and GD2, and are not laid in the region A2. Note that the scanning signal wirings GL3 to GL10 may also be formed to be laid across the region A2, similar to the data signal wirings DL2 to DL8.

In this embodiment, when an image is displayed, unevenness accompanied by an increase in luminance develops in a peripheral portion of the region A1. This is because, in the display area DA in the peripheral portion of the region A1, a difference in TFT characteristics causes a difference in luminance in the peripheral portion of the region A1. The difference in luminance is visually recognized as unevenness.

In order to reduce the unevenness in the peripheral portion of the region A1, dummy contact holes are concentrically arranged around the region A1.

At opposing sides of the region A1 in the y-direction, a wide spacing is provided between the routed wiring portion HL4 and the routed wiring portion HL5. Hence, the dummy contact holes can be readily arranged around the region A1.

However, at the opposing sides of the region A1 in the y-direction, spacings between the routed wiring portions HL2, HL3, and HL4 are narrow, and spacings between the routed wiring portions HL5, HL6, HL7, and HL8 are narrow. When the dummy contact holes are formed in the routed wiring portions HL2 to HL8, the routed wiring portions HL2 to HL8 might be broken because of level differences of the dummy contact holes. That is why the dummy contact holes have to avoid the routed wiring portions HL2 to HL8 for arrangement. Hence, it is difficult to concentrically arrange the dummy contact holes around the region A1.

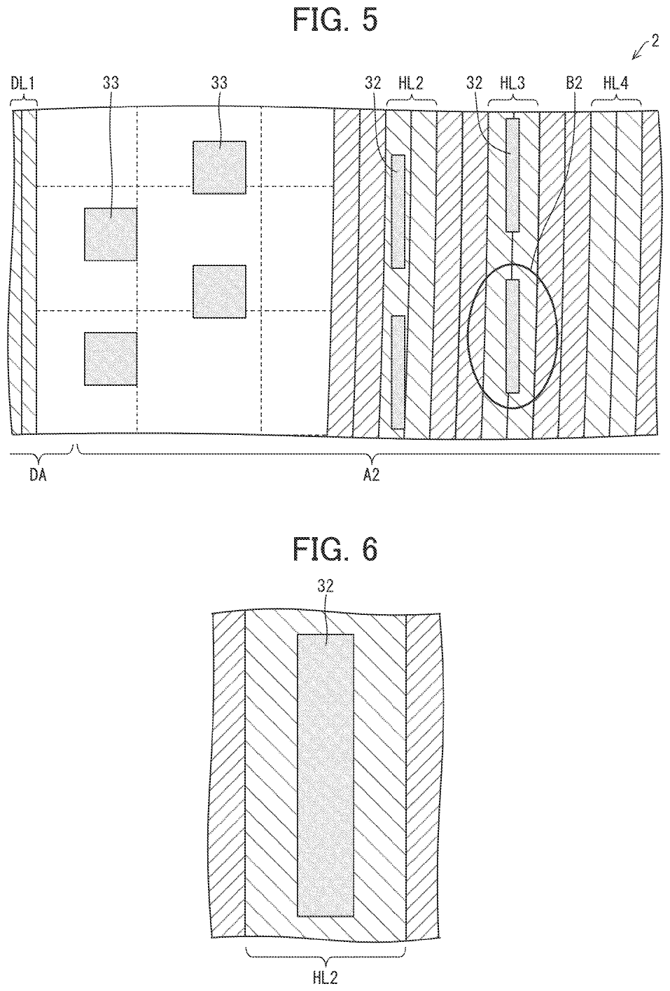

FIG. 5 is an enlarged plan view of a portion B1 illustrated in FIG. 4. FIG. 6 is an enlarged plan view of a portion B2 illustrated in FIG. 5. Identical reference signs are used to denote the identical constituent elements described before. Such constituent elements will not be elaborated upon repeatedly.

In order to reduce the unevenness in the peripheral portion of the region A1, dummy contact holes 32 are concentrically arranged around the region A1. Each of the dummy contact holes 32 is formed away from a portion of the routed wiring portion HL2 in a width direction, and formed to overlap with another portion of the routed wiring portion HL2 in the width direction.

Each of the dummy contact holes 32 is, as illustrated in FIGS. 5 and 6, preferably formed into a slit along the routed wiring portion HL2 so that a portion of either the routed wiring portion HL2 or HL3 in the width direction is left on opposing sides of the dummy contact hole 32. The dummy contact hole 32 has a size of, for example, 3 μm to 4 μm.

As illustrated in FIG. 5, the dummy contact holes 32 may be formed either in a center of the routed wiring portion HL3 in the width direction, or in the routed wiring portion HL2 toward the display area DA in the width direction.

Between the display area DA and the routed wiring portion HL2, a plurality of dummy contact holes 33 are formed, and each of the dummy contact holes 33 is substantially square.

Hence, the dummy contact holes 32 can be arranged in a portion in which routed wiring portions are provided so densely that it was previously difficult to arrange the dummy contact holes. As a result, the dummy contact holes 32 can be concentrically arranged around the region A1, in a similar arrangement and density as arranged in the display area DA. Such a feature can reduce variations in TFT characteristics in the display area DA.

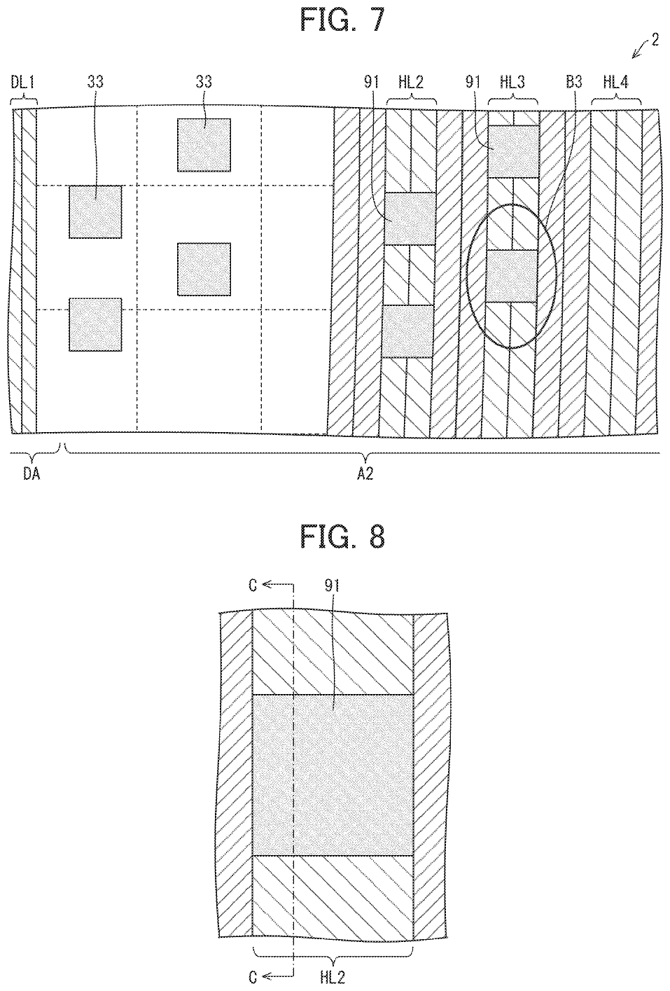

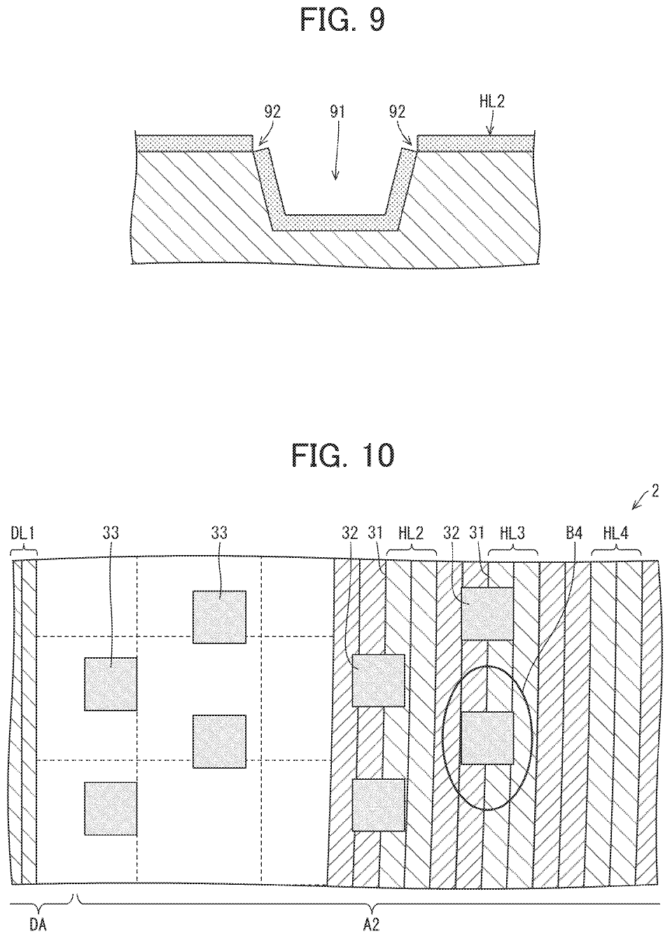

FIG. 7 is a plan view showing dummy contact holes 91 according to a comparative example. FIG. 8 is an enlarged plan view of a portion B3 illustrated in FIG. 7. FIG. 9 is a cross-sectional view along line C-C illustrated in FIG. 8. Identical reference signs are used to denote the identical constituent elements described before. Such constituent elements will not be elaborated upon repeatedly.

On the routed wiring portions HL2 and HL3, as illustrated in FIGS. 7 and 8, the dummy contact holes 91, each of which is substantially square, are formed across the routed wiring portions HL2 and HL3 in the width direction. Thus, as illustrated in FIG. 9, a level difference 92 develops in the routed wiring portion HL2 on an edge of the dummy contact hole 91. The level difference 92 could break the routed wiring portion HL2.

In contrast, as to the dummy contact holes 32 of this embodiment illustrated in FIGS. 5 and 6, even if a level difference develops in the routed wiring portion HL2 on an edge of a dummy contact hole 32, the routed wiring portion HL2 is continuous at opposing sides of the dummy contact hole 32. Such a feature eliminates the risk that the routed wiring portion HL2 would be broken.

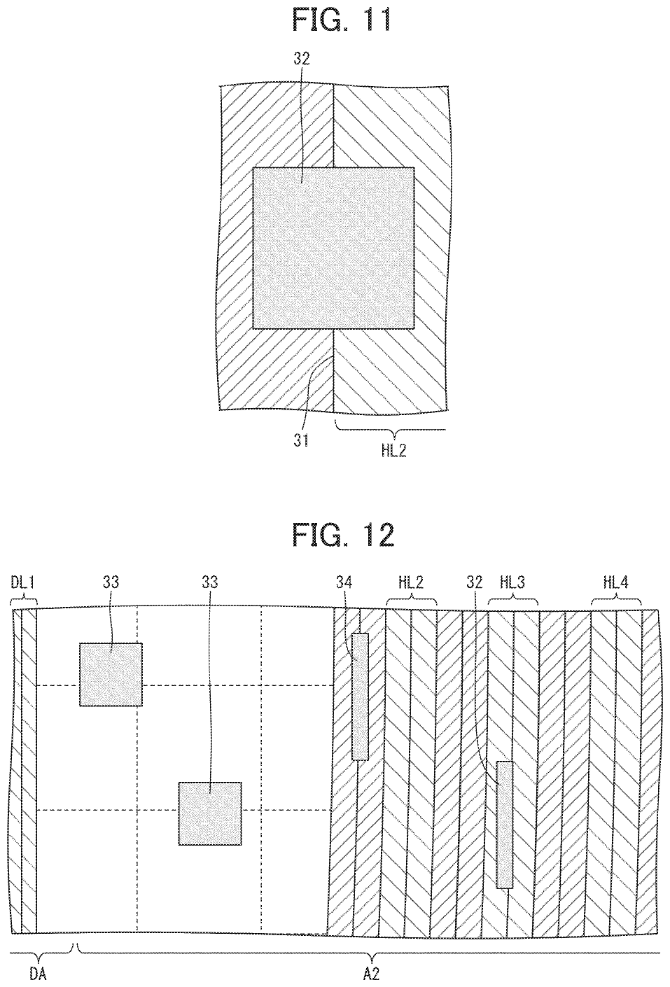

FIG. 10 is another enlarged plan view of the portion B1 illustrated in FIG. 4. FIG. 11 is an enlarged plan view of a portion B4 illustrated in FIG. 10. Identical reference signs are used to denote the identical constituent elements described before. Such constituent elements will not be elaborated upon repeatedly.

A dummy contact hole 32 may be formed to overlap with an end 31 of the routed wiring portion HL2 or HL3 in the width direction. If only a portion of the dummy contact hole 32 is disposed to overlap with a portion of the routed wiring portion HL2 or HL3 in the width direction, the rest of the routed wiring portion HL2 or HL3, which is not provided with the contact hole 32, eliminates the risk that the routed wiring portion HL2 or HL3 would be broken.

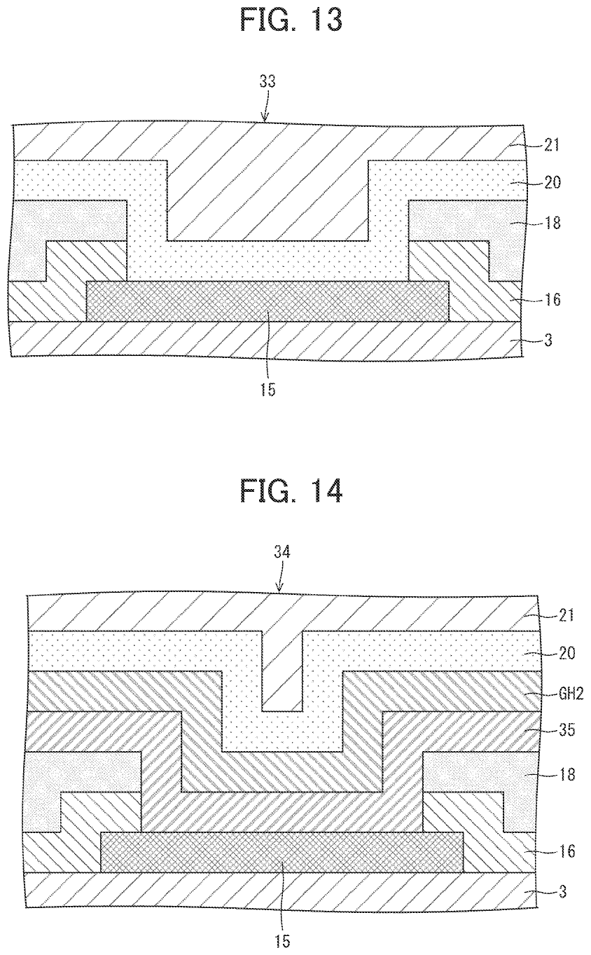

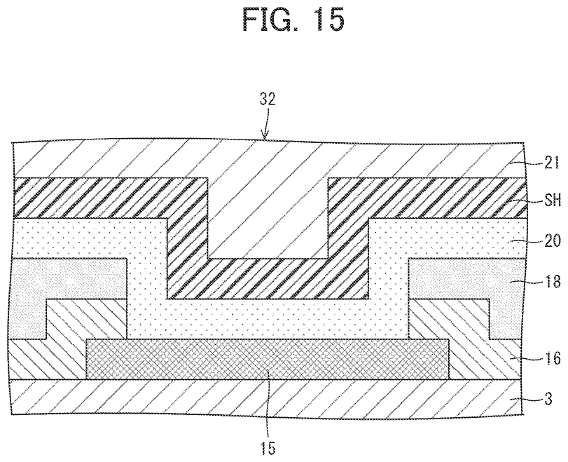

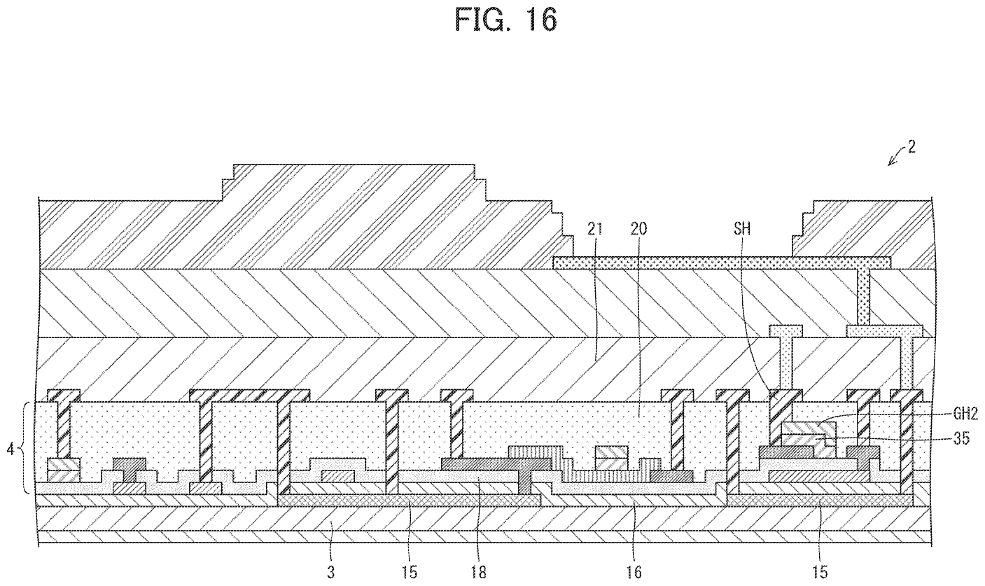

FIG. 12 is a plan view showing the dummy contact holes 32, 33, and 34 provided to the region A2 of the display device 2. FIG. 13 is a cross-sectional view of the dummy contact hole 33 formed between the display area DA and the routed wiring portion HL2. FIG. 14 is a cross-sectional view of the dummy contact hole 34 formed in the region A2 under a top gate metal GH2. FIG. 15 is a cross-sectional view of the dummy contact hole 32 formed in the region A2 under the routed wiring portion HL3. FIG. 16 is a cross-sectional view showing the dummy contact holes provided to the display device 2. Identical reference signs are used to denote the identical constituent elements described before. Such constituent elements will not be elaborated upon repeatedly.

The dummy contact hole 33 formed between the display area DA and the routed wiring portion HL2 is formed to reach the semiconductor film 15. The dummy contact hole 33 is filled with the inorganic insulating film 20 and the planarization film 21 in the stated order.

The dummy contact hole 34 formed in the region A2 under the top gate metal GH2 is formed to reach the semiconductor film 15. The dummy contact hole 34 is filled with the inorganic insulating film 35, the top gate metal GH2, the inorganic insulating film 20, and the planarization film 21 in the stated order.

The dummy contact hole 32 formed in the region A2 under the routed wiring portion HL3 is formed to reach the semiconductor film 15. The dummy contact hole 32 is filled with the inorganic insulating film 20, a source wiring SH, and the planarization film 21 in the stated order.

Note that each of the scanning signal wirings GL3 to GL10 may include a routed wiring portion that bypasses the region A1 and passes through the region A2.

The present invention shall not be limited to the embodiments described above, and can be modified in various manners within the scope of claims. The technical aspects disclosed in different embodiments are to be appropriately combined together to implement an other embodiment. Such an embodiment shall be included within the technical scope of the present invention. Moreover, the technical aspects disclosed in each embodiment may be combined to achieve a new technical feature.

### REFERENCE SIGNS LIST

2 Display Device
3 Barrier Layer
4 TFT Layer
5 Light-Emitting Element Layer
6 Encapsulation Layer
12 Resin Layer
15 Semiconductor Film
16, 18, and 20 Inorganic Insulating Films
21 Planarization Film
23 Edge Cover
24 EL Layer
31 End
32 Dummy Contact Hole
33 Dummy Contact Hole
34 Dummy Contact Hole
35 Inorganic Insulating Film
DA Display Area
NA Picture-Frame Region
A1 Region (First Region, Camera Hole)
A2 Region (Second Region)
GL Scanning Signal Wiring
DL Data Signal Wiring
GL1 to GL 10 Scanning Signal Wirings
DL1 to DL 10 Data Signal Wirings
HL2 to HL8 Routed Wiring Portions

1. A display device having a display area including: a plurality of scanning signal wirings; a plurality of data signal wirings intersecting with the plurality of scanning signal wirings; and a plurality of subpixel circuits each disposed to a corresponding one of a plurality of intersections of the plurality of scanning signal wirings and the plurality of data signal wirings, the display device comprising
a first region and a second region not provided with the plurality of subpixel circuits, the first region being surrounded with the second region and the second region being surrounded with the display area,
wherein, when viewed in a direction perpendicular to the display area, each of a plurality of signal wirings includes a routed wiring portion that bypasses the first region and passes through the second region, the plurality of signal wirings at least including: scanning signal wirings included in the plurality of scanning signals; or data signal wirings included in the plurality of data signal wirings, and
the display device comprises a dummy contact hole formed away from a portion of the routed wiring portion in a width direction, and formed to overlap with another portion of the routed wiring portion in the width direction.

2. The display device according to claim 1,
wherein the dummy contact hole is formed into a slit along the routed wiring portion so that the portion of the routed wiring portion in the width direction is left on opposing sides of the dummy contact hole.

3. The display device according to claim 1,
the dummy contact hole is formed to overlap with an end of the routed wiring portion in the width direction.

4. The display device according to claim 1,
wherein the dummy contact hole is disposed perpendicularly to a longitudinal direction of the plurality of signal wirings with respect to the first region.

5. The display device according to claim 1,
wherein, each of data signal wirings included in the plurality of data signal wirings includes a routed wiring portion that bypasses the first region and passes through the second region, and
first scanning signal wirings of the scanning signal wirings included in the plurality of the scanning signal wirings are connected to one of a pair of gate drivers arranged at opposing sides of the display area, and second scanning signal wirings of the scanning signal wirings included in the plurality of the scanning signal wirings are connected to another one of the pair of gate drivers.

6. The display device according to claim 1,
wherein the first region is provided with a camera hole for imaging.

7. The display device according to claim 1,
wherein a spacing between routed wiring portions adjacent to one another and passing through the second region is narrower than a spacing between the signal wirings adjacent to one another and passing through the display area, the routed wiring portions being included in the routed wiring portion.

8. The display device according to claim 1,
wherein each of the plurality of subpixel circuits includes: a control circuit including a transistor; a reflective electrode; a light-emitting element; and a transparent electrode.

9. The display device according to claim 1,
wherein, each of the scanning signal wirings included in the plurality of scanning signal wirings includes the routed wiring portion.
